(19) United States
(12) Patent Application Publication
(10) Pub. No.: US 2017/0271839 A1
(43) Pub. Date: Sep. 21, 2017

(54) METHOD FOR FABRICATING SURFACE EMITTING LASER

(71) Applicant: SUMITOMO ELECTRIC INDUSTRIES, LTD., Osaka (JP)

(72) Inventor: Yukihiro TSUJI, Yokohama-shi (JP)

(73) Assignee: SUMITOMO ELECTRIC INDUSTRIES, LTD., Osaka (JP)

(21) Appl. No.: 15/457,188

(22) Filed: Mar. 13, 2017

(30) Foreign Application Priority Data
Mar. 15, 2016 (JP) 2016-051269

(51) Int. Cl. H01S 5/02; H01S 5/18

(52) U.S. Cl. CPC H01S 5/0205; H01S 5/18; H01S 5/0203; H01S 2304/00

(57) ABSTRACT

A method for fabricating a surface emitting laser includes the steps of: carrying out etching of a semiconductor laminate with a mask; and stopping the etching in response to a detection signal from an end point detector in an etching apparatus. The mask has a device area including device sections and an accessary area. The device area has an aperture ratio (OPD/SC) having a first value, the aperture ratio (OPD/SC) being defined as a total area (OPD) of an opening in each device section to an area (SC) of the device section. The accessary area has an aperture ratio having a second value configured to have substantially the same value as the first value, the aperture ratio of the accessary area being defined as an area of the opening pattern in a portion having an area, which is equal to the area of the device section, in the accessary area.

### BACKGROUND OF THE INVENTION

Field of the Invention

The present invention relates to a method for fabricating a surface emitting laser. This application claims the benefit of priority from Japanese Patent Application No. 2016-051269 filed on Mar. 15, 2016, which is herein incorporated by reference in its entirety.

Related Background Art

M W DeVre, Y S Lee, B H Reelfs, R J Westerman, and S D Roh, “Characterization of GaAs/AlGaAs non-selective ICP etch process for VCSEL applications,” (Non-Patent Document 1) discloses an etching applied to a fabrication of a vertical cavity surface emitting laser. Non-Patent Document 1 is downloaded from the following URL. http://www.plasma-therm.com/technical-papers.html#Etching, specifically, http://www.plasma-therm.com/pdfs/papers/33.%20Characterization%20of%20Ga As—AlGaAs%20non-selective/020ICP%20etch%20p.pdf.

### SUMMARY OF THE INVENTION

A vertical cavity surface emitting laser includes a semiconductor post in which a laser cavity is included, and the semiconductor post includes stacked semiconductor layers constituting respective distributed Bragg reflectors and a quantum well structure constituting an active layer provided between the stacked semiconductor layers. In the fabrication of the vertical cavity surface emitting laser, a thick semiconductor multilayer film is etched to form an array of semiconductor posts on a substrate. Variation in height of the semiconductor posts of the vertical cavity surface emitting lasers relates to the performance thereof.

Inventor's studies reveal that the variation in height is associated with the detection of the end point in the etching process to form the array of semiconductor posts. Specifically, difficulties in the etching are associated with not only complexity in the multilayer structure and a large thickness of the multilayer structure but also the pattern of the area to be etched. In the etching process, a plurality of marks, such as an alignment mark, are also formed on the substrate. The marks are utilized in subsequent processes.

A method for fabricating a surface emitting laser according to an aspect of the present invention includes the steps of: growing a semiconductor laminate on a substrate to form an epitaxial substrate; forming a mask on the epitaxial substrate, the mask defining a semiconductor post of the surface emitting laser, the mask having a device area and an accessary area; after forming the mask, placing the epitaxial substrate in a chamber of an etching apparatus with an end point detector; carrying out etching of the semiconductor laminate with the mask in the chamber of the etching apparatus; and stopping the etching of the semiconductor laminate in response to a detection signal from the end point detector in the etching apparatus. The device area includes a plurality of device sections arranged in row and column. Each of the device sections has an opening. The device area has an aperture ratio (OPD/SC) having a first value, the aperture ratio (OPD/SC) of the device area being defined as a total area (OPD) of the opening in each device section to an area (SC) of the device section. The accessary area has an aperture ratio having a second value configured to have substantially the same value as the first value, the aperture ratio of the accessary area being defined as an area of the opening pattern in a portion having an area, which is equal to the area of the device section, in the accessary area.

The above-described objects and the other objects, features, and advantages of the present invention become more apparent from the following detailed description of the preferred embodiments of the present invention proceeding with reference to the attached drawings.

### BRIEF DESCRIPTION OF THE DRAWINGS

FIG. 1 is a view showing major steps in a method for fabricating a surface emitting laser according to the present embodiment.

FIG. 2 is a view showing major steps in the method for fabricating the surface emitting laser according to the present embodiment.

FIG. 3 is a plan view showing a shot map on the principal surface of the epitaxial substrate according to the present embodiment.

FIG. 4 is a plan view showing a pattern of a mask in a size of one shot.

FIG. 5 is a plan view showing a pattern of another mask in a size of one shot.

FIG. 6 is a schematic view showing an exemplary etching apparatus applicable to the present embodiment.

FIG. 7 is a view showing major steps in the method for fabricating the surface emitting laser according to the present embodiment.

FIG. 8 is a view showing a waveform provided by the wavelength-monitoring end point detector in etching the epitaxial substrate with the mask shown in FIG. 4.

FIG. 9 is a view showing a waveform provided by the wavelength-monitoring end point detector in etching the epitaxial substrate with the mask shown in FIG. 5.

FIG. 10 is a view showing major steps in the method for fabricating the surface emitting laser according to the present embodiment.

FIG. 11 is a view showing major steps in the method for fabricating the surface emitting laser according to the present embodiment.

FIG. 12 is a view showing major steps in the method for fabricating the surface emitting laser according to the present embodiment.

FIG. 13 is a view showing major steps in the method for fabricating the surface emitting laser according to the present embodiment.

### DESCRIPTION OF THE EMBODIMENTS

Specific embodiments according to the present above aspect are described below.

A method for fabricating a surface emitting laser according to an embodiment of the present invention includes the steps of: (a) growing a semiconductor laminate on a substrate to form an epitaxial substrate; (b) forming a mask on the epitaxial substrate, the mask defining a semiconductor post of the surface emitting laser, the mask having a device area and an accessary area; (c) after forming the mask, placing the epitaxial substrate in a chamber of an etching apparatus with an end point detector; (d) carrying out etching of the semiconductor laminate with the mask in the chamber of the etching apparatus; and (e) stopping the etching of the semiconductor laminate in response to a detection signal from the end point detector in the etching apparatus. The device area includes a plurality of device sections arranged in row and column. Each of the device sections has an opening. The device area has an aperture ratio (OPD/SC) having a first value, the aperture ratio (OPD/SC) of the device area being defined as a total area (OPD) of the opening in each device section to an area (SC) of the device section. The accessary area has an opening pattern. The accessary area has an aperture ratio having a second value configured to have substantially the same value as the first value, the aperture ratio of the accessary area being defined as an area of the opening pattern in a portion having an area, which is equal to the area of the device section, in the accessary area.

In the method of fabricating the surface emitting laser, the etching of the semiconductor laminate for the surface emitting laser is carried out by processing a semiconductor multilayer film including stacked semiconductor layers for respective distributed Bragg reflectors and a semiconductor layer constituting an active layer for light emission. The processing of the semiconductor multilayer film forms an array of semiconductor posts having the heights with a small variation. The end of the etching at which the posts have been formed is detected with the end point detector. Inventor's teachings reveal that the end point detector monitors an area with a larger size than each of the device sections during etching, and the product in the fabricating steps includes an accessary area for the structure used in applying subsequent processes thereto in addition to the device area for the device sections. During the etching, the end point detector provides an output signal which superposes an etching progress in the accessary area on an etching progress in the device area. Inventor's studies reveal that the superposition affects the accuracy of the end point detection. The superposition is, however, inevitable in view of the fabricating process requiring the product to have both the device area of the device sections and the accessary area of the structure. It is important to accurately monitor the progress of etching in the area of the device section. Furthermore, it is found that the superposition causes deterioration in the accuracy of the end point detection, which results from the difference between the progress of etching in the area of the accessary structure and the progress of etching in the area of the device sections of the mask. The primary factor of the difference between the progresses of etching in these areas lies in the difference in pattern between the ratio of opening for the area of the accessary structure and the ratio of opening for the area of the device section. Therefore, in order to accurately monitor the progress of etching in the area of the device section, the opening ratio of the device area and the opening ratio of the accessary area should be adjusted in the pattern of the mask for etching. This adjustment results in reducing the deterioration in accuracy of the end point detection.

In the method according to an embodiment, preferably, each of the device sections in the device area includes a first opening having a closed shape defining a pattern for the semiconductor post. The accessary area has an area larger than that of the device section. In addition, the second value is equal to or larger than a lower limit which is smaller by 0.02 with respect to the first value and is equal to or less than an upper limit which is larger by 0.02 with respect to the first value.

In the method according to an embodiment, the device area may include a second opening different from the first opening disposed in each of the device sections.

The method for fabricating the surface emitting laser allows the addition of the second opening in the device area to make the aperture ratio of the device area close to the aperture ratio of the accessary area.

In the method according to an embodiment, the end point detector may include a spectrometer for monitoring an optical emission in the etching.

In the method according to an embodiment, the etching may be carried out by using an inductive-coupling plasma reactive-ion etching method.

In the method for fabricating the surface emitting laser, the inductively coupled plasma reactive-ion etching method is suitable for forming the semiconductor post of the surface emitting laser.

In the method according to an embodiment, the etching may be carried out by using BCl₃ as an etchant.

In the method for fabricating the surface emitting laser, the semiconductor post with an excellent shape is formed by etching using boron trichloride as an etchant in the etching process.

In the method according to an embodiment, the opening pattern in the accessary area may include a plurality of openings that defines an alignment mark.

In the method for fabricating the surface emitting laser, defining a pattern for the alignment mark by a plurality of openings makes it easy to bring the aperture ratio of the accessary area close to the aperture ratio of the device area.

Teachings of the present invention can be readily understood by considering the following detailed description with reference to the accompanying drawings shown as examples. Referring to the accompanying drawings, embodiments of a method for fabricating a surface emitting laser according to the present invention will be described. To facilitate understanding, identical reference numerals are used, where possible, to designate identical elements that are common to the figures.

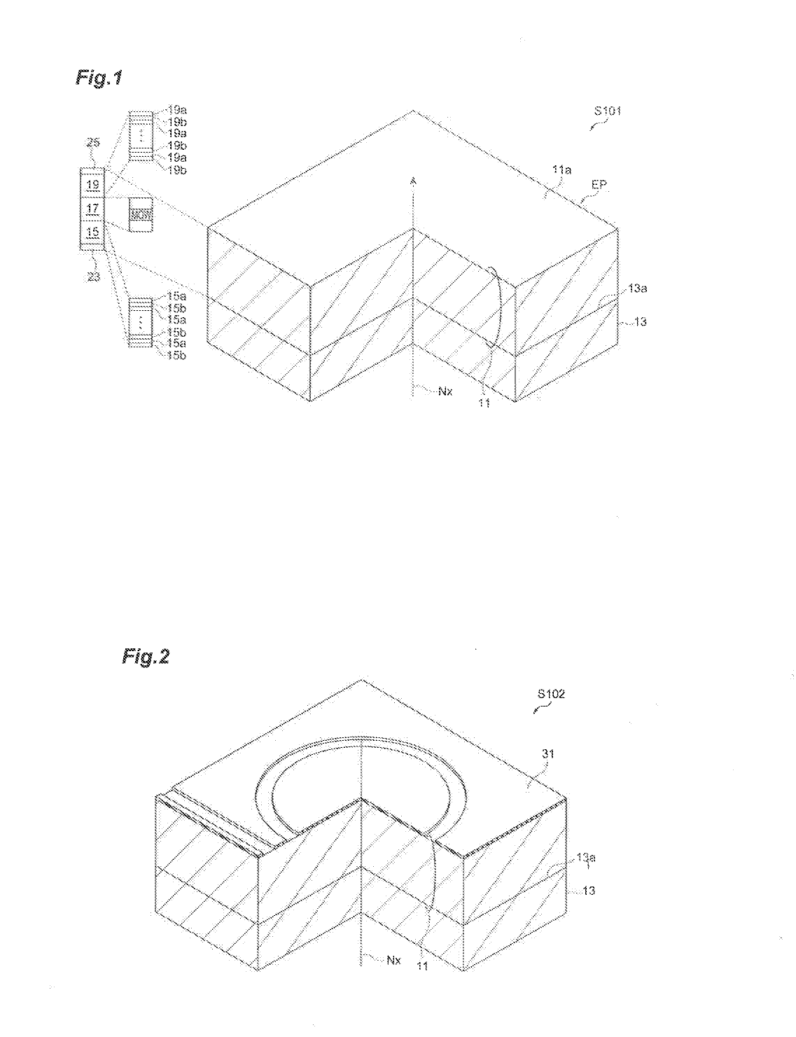

With reference to FIGS. 1 to 13, a method for fabricating a surface emitting laser will be described below. FIGS. 1, 2, 7, 3, and 10 to 13 each show a single device section of the surface emitting laser to be fabricated. The present embodiment describes an exemplary fabrication of a vertical cavity surface emitting laser (VCSEL).

In step S101, as shown in FIG. 1, an epitaxial substrate EP is prepared for fabrication of the surface emitting laser. The epitaxial substrate EP includes a laminate 11 and a substrate 13, and the laminate 11 is provided on a principal surface 13a of the substrate 13. In the embodiment, the laminate 11 serves as a semiconductor laminate. The laminate 11 includes a first stacked semiconductor layer 15 constituting a first distributed Bragg reflector, a semiconductor region 17 constituting an active layer, and a second stacked semiconductor layer 19 constituting a second distributed Bragg reflector. The first stacked semiconductor layer 15, the semiconductor region 17 and the second stacked semiconductor layer 19 are arranged in the direction of an axis Nx normal to axis of the principal surface 13a of the substrate 13. The semiconductor region 17 may include a quantum well structure MQW serving as the active layer for light emission. If necessary, the laminate 11 of the epitaxial substrate EP may include an upper contact layer 25. The laminate 11 may contain a III-V semiconductor layer 23 as an etching-stop layer for use in monitoring the etching for forming semiconductor posts, which is to be produced in a subsequent step, and the III-V semiconductor layer 23 is in, for example, the first stacked semiconductor layer 15. In the embodiment, in order to prepare the epitaxial substrate EP, the epitaxial substrate EP is formed in the following process. The substrate 13 is prepared for growing semiconductor layers thereon by using an epitaxial growth method. The substrate 13 may include a semiconductor wafer, such as, a GaAs wafer. The laminate 11 is grown on the principal surface 13a of the substrate 13 by using, for example, a molecular beam epitaxy method and/or a metal-organic vapor phase epitaxy method to form the epitaxial substrate EP. The first stacked semiconductor layer 15 in the laminate 11 includes first semiconductor layers 15a and second semiconductor layers 15b, which are alternately arranged in the direction of the normal axis Nx to form one distributed Bragg reflector. The second stacked semiconductor layer 19 in the laminate 11 includes third semiconductor layers 19a and fourth semiconductor layers 19b, which are alternately arranged in the direction of the normal axis Nx to form the other distributed Bragg reflector.

Exemplary epitaxial substrate EP

First stacked semiconductor layer 15: GaAs/AlGaAs superlattice.
First semiconductor layer 15a: GaAs.
Second semiconductor layer 15b: AlGaAs.
III-V semiconductor layer 23: GaAs, Al(x)Ga(1−x)As (x is zero or more and 0.1 or less).
The group III-V semiconductor layer 23 contains gallium as a group III constituent element, and contains aluminum of 10% or less as a group III constituent element. The group III-V semiconductor layer 23 is disposed between two semiconductor layers of AlGaAs containing aluminum of 50% or more and is in contact therewith.
Semiconductor region 17.
Quantum well structure MQW: AlGaAs/GaAs.
Second stacked semiconductor layer 19: GaAs/AlGaAs superlattice.
Third semiconductor layer 19a: GaAs.
Fourth semiconductor layer 19b: AlGaAs.
Upper contact layer 25: GaAs.

In step S102, as shown in FIG. 2, a mask 31 is formed on the epitaxial substrate EP. The mask 31 defines the shape of the semiconductor post in which the optical cavity is formed. In the fabrication of the mask 31, first, an inorganic insulating film (for example, a silicon-based inorganic insulating film, such as silicon oxide film, silicon nitride film, and silicon oxynitride film) is formed on a principal surface 11 a of the laminate 11 of the epitaxial substrate EP; and the inorganic insulating film is processed by using the photolithography method and the etching technique. Specifically, resist is applied on the inorganic insulating film. A resist mask having a pattern for forming the semiconductor post is formed by using the photolithography method. The inorganic insulating film is etched by using the resist mask. As a result, the pattern of the resist mask is transferred to the inorganic insulating film so as to form the mask 31, which has the pattern for forming the semiconductor post.

FIG. 3 is a plan view showing a shot map on the principal surface of the epitaxial substrate according to the present embodiment. The substrate 13 may be a commercially available GaAs wafer, which has an exemplary shape with a circular arc CV and an orientation flat OF. In FIG. 3, a shot SHOT to be exposed in a step-and-repeat manner by a reduction projection exposure system is drawn on a GaAs wafer by broken lines. By the exposure, a desired pattern on the reticle is transferred to the resist for each shot SHOT. The resist thus exposed is developed to form the resist mask. The resist pattern of the resist mask has an array of shots SHOT composed of a repetition of a pattern on the reticle. The inorganic insulating film is etched with the resist mask, and the resist mask is removed off after the etching. These processes complete a patterned inorganic insulating film, i.e., the mask 31.

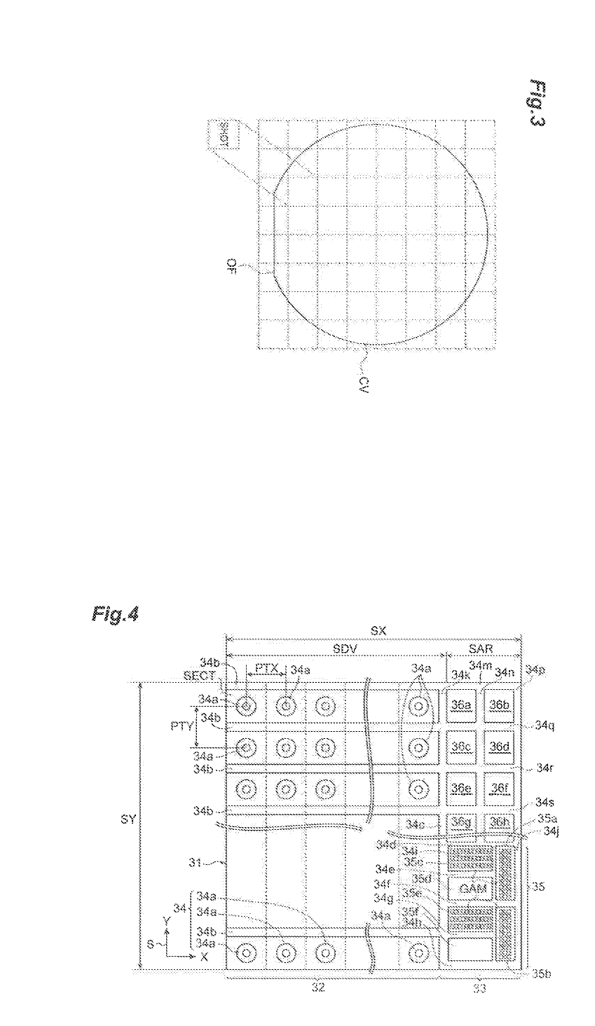

FIG. 4 is a plan view showing a pattern of the mask 31 in a size of one shot. In FIG. 4, an orthogonal coordinate system S is also drawn.

The shot SHOT in the mask 31 includes a device area 32 and an accessary area 33. The device area 32 includes device sections SECT arranged in rows and columns. The device area 32 has opening patterns 34 (for example, a first opening 34a and a second opening 34b).

Exemplary single shot SHOT.
Size in the X direction (SX): 10000 micrometers.
Size in the Y direction (SY): 10000 micrometers.
Size of the device area 32.
Size in the X direction (SDV): 7500 micrometers.
Size in the Y direction (SY): 10000 micrometers.
Size of the accessary area 33.
Size in X direction (SAR: 2500 micrometers.
Size in the Y direction (SY): 10000 micrometers.
In the present embodiment, the opening pattern 34 in the device area 32 includes a first opening 34a of a looped shape which is provided in each of the device sections SECT and defines the shape of the semiconductor post, and a second opening 34b having a strip shape and extending across the device sections SECT from one end of the device area 32 to the other end.
Exemplary opening pattern 34 of the device area 32.
First opening 34a: 15 micrometers in width, 30 micrometers in inner diameter, and 60 micrometers in outer diameter.
A semiconductor post having a diameter of 30 micrometers may be formed.
Second opening 34b: 15 micrometers in width.
The device section SECT has a pitch of 250 micrometers in the X direction and a pitch of 250 micrometers in the Y direction.

The device area 32 includes the first openings 34a and one or more second openings 34b. In the device area 32, the first openings 34a form a two-dimensional array with pitches of the device size in the directions of the X- and Y-axes. Each of the second opening 34b may extend in the direction of at least one of the X-or Y-axis, and the pitches in the arrangement of the second openings 34b corresponds to those of the device sections. In the present embodiment, the second openings 34b are arranged in the Y-axis direction and extend in the X-axis direction so as to form a stripe shape. Alternatively, the single second opening, 34b may extend in both the X-axis and the Y-axis to form a lattice-shape, and the pitches in the X- and Y-axes may be the same as those of the arrangement of the device sections.

In the present embodiment, the width of the first opening 34a and the width of the second opening 34b both are 15 micrometers, and the width of the first opening 34a may be different from the width of the second opening 34b within a certain allowable range. Such an allowable range may be determined as follows, for example. Prior to the determination of the reticle pattern, the following masks are prepared: a mask providing a shot in which the width of the first opening 34a and the width of the second opening 34b are the same as each other (for example, the width of the first opening 34a is equal to the width of the second opening 34b); a mask providing a shot in which the width of the first opening 34a and the width of the second opening 34b are different from each other (for example, the width of the first opening 34a is less than the width of the second opening 34b); and a mask for providing a shot in which the width of the first opening 34a and the width of the second opening 34b are different from each other (for example, the width of the first opening 34a is more than the width of the second opening 34b). A semiconductor substrate or an epitaxial substrate having a semiconductor layer epitaxially grown on the substrate is etched by using these masks to determine the width of the first opening 34a and the width of the second opening 34b. in the dry etching process, the plasma emission spectroscopy is used for the end point monitor. The width of the first opening 34a and the width of the second opening 34b relate to the monitoring waveform for the end point detection when the plasma emission spectroscopy is used as the end point monitor. The results of the etchings are analyzed to determine the opening width allowing the monitoring waveform for the end point detection to achieve a desired accuracy. The results of similar etching experiments may be also used to determine the arrangement and extension of the second openings 34n (either the X- or Y-axis or both the X- and Y-axes) with a desired accuracy. As understood from the experiments as described above, in the present embodiment, the opening pattern 34 of the device area 32 may include the first opening 34a and the second opening(s) 34b, but if necessary, may include a third opening.

The aperture ratio of the device area 32 is defined as a ratio (OPD/SC) of the total area of the openings in the device section (OPD: for example, the sum of the areas of the first opening 34a and the second opening 34b in a single device section) to the device area (SC: 250×250 μm² in the present embodiment) of a single device section SECT. Calculations according to the above definition are carried out for the area of the device section in the individual mask 31 to obtain the value of the aperture ratio (this value is referred to as “the first value” in the following description).

As shown in FIG. 4, the accessary area 33 has a size larger than the device area of the single device section SECT. The accessary area 33 has opening patterns. The alignment mark area 35 is provided with marks prepared for alignment for exposure in a subsequent process. In optical alignment in the subsequent process, the reflection of light is associated with the marks. In the present embodiment, the alignment marks are defined as follows. The accessary area 33 has a pattern for forming semiconductor stack islands 35a, 35b, 35c, 35d, 35e, and 35f, and at least one of the semiconductor stack islands 35a, 35b, 35c, 35d, 35e, 35f has a pattern with an arrangement of openings GAM which generate the reflection from the arrangement of the holes in the alignment mark. In the alignment mark to be formed, holes are arranged in the direction of the X-axis to define an X alignment mark and other holes are arranged in the direction of the Y-axis to define a Y alignment mark. The size of each hole may be, for example, 5 μm×5 μm.

The accessary area 33 includes openings 34c, 34d, 34e, 34f, 34g, 34h, 34i, and 34j that define the semiconductor stack islands 35a, 35h, 35c, 35d, 35e, and 35f. If necessary, the remaining area of the accessary area 33 may be provided with check patterns for various measurements in the fabricating process. The remaining area also has a pattern for forming semiconductor stack islands 36a, 36b, 36c, 36d, 36e, 36f, 36g, and 36h, and the pattern has openings 34k, 34m, 34n, 34p, 34q, 34r, and 34s that define the semiconductor stack islands 36a, 36b, 36c, 36d, 36e, 36f, 36g, 36h. The opening 34k is connected to the opening 34c. The opening 34p is connected to the opening 34j. The openings 34m, 34q, 34r, and 34s are connected to the respective second openings 34b. The above description provides the explanation of an exemplary pattern, and the present embodiment is not limited to the shape and arrangement of the specific pattern as above.

The aperture ratio of the accessary area 33 is defined as a ratio of a total area of the opening pattern in the accessary area 33 having the same area as the area (SC) of the device section to the area (SC) of the device section. The aperture ratio of the accessary area 33 is referred to as a second value. The second value of the aperture ratio can be calculated per an area, which is equal to the area of the device section, in the accessary area 33.

The aperture ratio of the accessary area 33 is defined as an area of the opening pattern in a portion having an area, which is equal to the area of the device section, in the accessary area 33. The aperture ratio of the accessary area 33 is referred to as a second value. The second value of the aperture ratio can be calculated per an area, which is equal to the area of the device section, in the accessary area 33. The second value may not be constant at the portions in the accessary area 33. In this case, the average value of the second values in the accessary area 33 may be used as a typical second value, for example. Preferably, the opening pattern in the accessary area 33 is formed so as to obtain the substantially uniform second value in a plurality of portions having an area, which is equal to the area of the device section, in the accessary area 33.

To perform the subsequent etching easily the aperture ratio (the first value) in the device area 32 ranges, for example, from 0.06 to 0.10. The aperture ratio of the device area 32 of the lower limit value or more can prevent the end point Monitor for the plasma emission spectroscopy from receiving the superposed signal including signal components from respective regions where the etching rate is larger and where the etching rate is smaller, thereby suppressing noise in the signal thus received. The aperture ratio of the device area 32 of the upper limit value or lower allows in-plane variation in etching rate to be not more than 5%, thereby making the in-plane uniformity in the etching depth excellent.

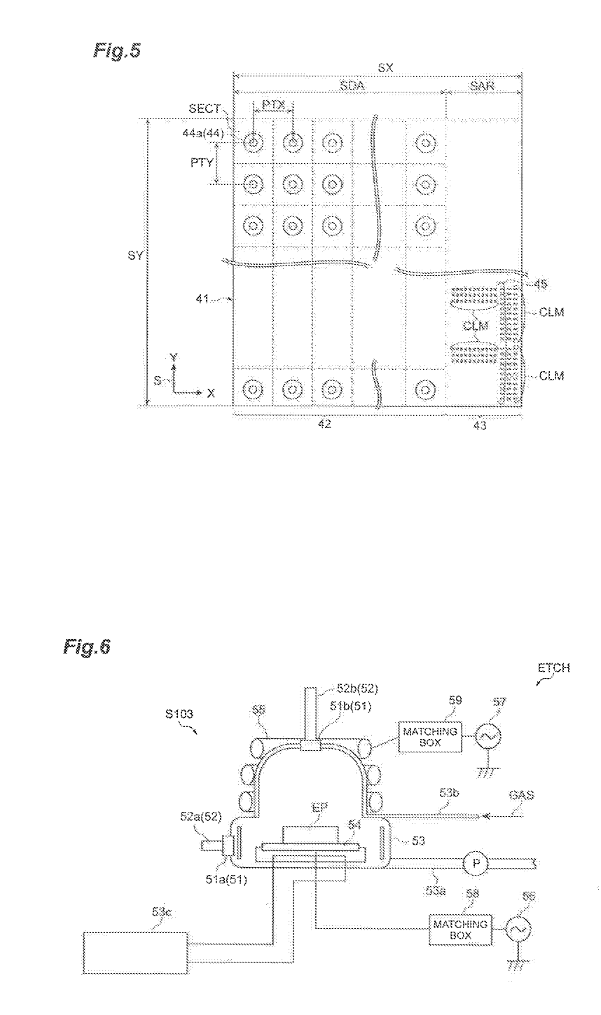

FIG. 5 is a plan view showing a pattern of another mask in a single shot. In FIG. 5, an orthogonal coordinate system S is drawn. A single shot of the mask 41 includes a device area 42 and an accessary area 43. The device area 42 includes device sections SECT arranged in rows and columns. The device area 42 has a single kind of opening pattern which is an opening pattern 44.

Exemplary single shot SHOT.
Length in the X direction (SX): 10000 micrometers.
Length in the Y direction (SY): 10000 micrometers.
Size of the device area 42.
Length in the X direction (SDV): 7500 micrometers.
Length in the Y direction (SY): 10000 micrometers.
Size of accessary area 43.
Length in the X direction (SAR): 2500 micrometers.
Length in the Y direction (SY): 10000 micrometers.
In the present embodiment, the opening pattern 44 of the device area 42 includes a first looped opening 44a which is provided in each of the device sections SECT.
The first looped opening 44a defines a semiconductor post.
An exemplary opening pattern 44 of the device area 42.
First opening 44a: 15 micrometers in width, 30 micrometers in inner diameter, and 60 micrometers in outer diameter.
Device section SECT: a pitch of 250 micrometers in the X direction and a pitch of 250 micrometers in the Y direction. In the device area 42, the first openings 44a are arranged at pitches of the device size in the directions of the X- and Y-axes to form a two-dimensional array. In the mask 41, the width of the first opening 44a is 15 micrometers which is the same as that of the first opening 34a.

In the device area 42, the aperture ratio is defined as a ratio (OPD/SC) of the sum of the area of openings (OPD: the first openings 44a per the single device section SECT) to the single device section SECT in the device area (SC: 250×250 micrometers square in the present embodiment). The definition allows the calculation for each mask 41 in the area of the device section.

As shown in FIG. 5, the accessary area 43 has a size larger than the device area of the single device section SECT. The accessary area 43 has a single kind of opening pattern. The alignment mark area 45 is provided with a mark for alignment for exposure in a subsequent step. Optical alignment requires the reflection of light from the edge of the mark. In the present embodiment, the alignment mark is produced as follows. The accessary area 43 includes a covering pattern for the alignment mark having an arrangement of columns CLM (columns) which enables reflection of light. In alignment marks to be formed, columns are arranged in the direction of the X-axis to define an X-alignment mark and other columns are arranged in the direction of the Y-axis to define a Y-alignment mark. Each column has a size of, for example, 5×5 micrometers square.

The aperture ratio in the accessary area 43 is defined with respect to a size equal to that of the device section. That is, the aperture ratio of the accessary area 43 is defined as a ratio of a total area of the opening pattern in the accessary area having the same area as the area (SC) of the device section to the area (SC) of the device section. The accessary area 43, however, includes an arrangement of islands which are defined by a single opening (the mask 41 has a pattern for forming an array of columns made of semiconductor layers). The aperture ratio of the device area 42 is smaller than that of the accessary area 43,

In step S103, an apparatus for etching is prepared. FIG. 6 is a schematic view showing an exemplary etching apparatus which is used in the present embodiment. The etching apparatus ETCH of FIG. 6 includes an inductively coupled plasma reactive-etching (ICP-RIE) device. The etching apparatus ETCH includes a view port 51 (51a and 51b), an end point detector 52 (52a and 52b), a chamber 53, a lower electrode 54, an inductive-coupling coil 55, a first radio frequency power supply 56, and a second radio frequency power supply 57. The chamber 53 is connected to an exhaust pump P through an exhaust path 53a and is connected to a gas inlet system 53b for supplying a gas GAS, such as a process gas and a source gas. The chamber 53 includes a dielectric dome, and the inductive coupling coil 55 is provided outside the dielectric dome of the chamber 53. The lower electrode 54 is provided inside the chamber 53. The epitaxial substrate EP is placed on the lower electrode 54. The first radio frequency power supply 56 is coupled to the lower electrode 54 through a first matching unit 58. The second radio frequency power supply 57 is coupled to the inductive-coupling coil 55 through a second matching unit 59. In the present embodiment, the view port 51a is provided on the side wall of the chamber 53, so that the view port 51a receives emission of light from the plasma generated above the lower electrode 54 (i.e., the epitaxial substrate EP on the lower electrode 54). The end point detector 52a receives light (light from the plasma), generated in the dielectric dome, through the view port 51a. If necessary, the lower electrode 54 is connected to a cooler 53c for adjusting the temperature of the substrate subjected to an etching process.

The end point detector 52 detects the end point of an etching process through the view port 51 of the etching apparatus ETCH. The end point detector 42a has a wavelength monitoring type. The end point detector can monitor wavelength of light and estimate the intensity of light emission of the constituent element(s) of semiconductor, which is etched, in the plasma, thereby detecting the end point in the etching process. The end point detector 42a includes a spectroscope for monitoring the emission in the etching process.

In step S104, as shown in FIG. 7, after forming the mask 31, the epitaxial substrate EP is placed on the lower electrode 54 of the etching apparatus ETCH. The chamber of the etching apparatus ETCH can be evacuated, and a process gas is supplied to the chamber to form a desired atmosphere therein by use of an exhaust pump. After the vacuum evacuation, a gas including the etchant in addition to the process gas is supplied to the chamber 53. The process gas may include, for example, hydrogen and/or helium. The etchant may include, for example, boron trichloride (BCl₃) and/or chlorine (Cl₂).

As shown in FIG. 6, an end point detector 52a (acting as an end point detection monitor), such as a wavelength-monitoring end point detector, is installed in the view port 51a. The view port 51a is disposed on the chamber 53 in the lateral direction of the wafer chuck, and the end point detector 52a receives emission from the plasma through the viewport 51a. The end point detector 52a monitors light having a desired wavelength with a spectroscope therein. The end point detector 52a is set to monitor the emission of light from Ga in the present embodiment.

### EXAMPLE

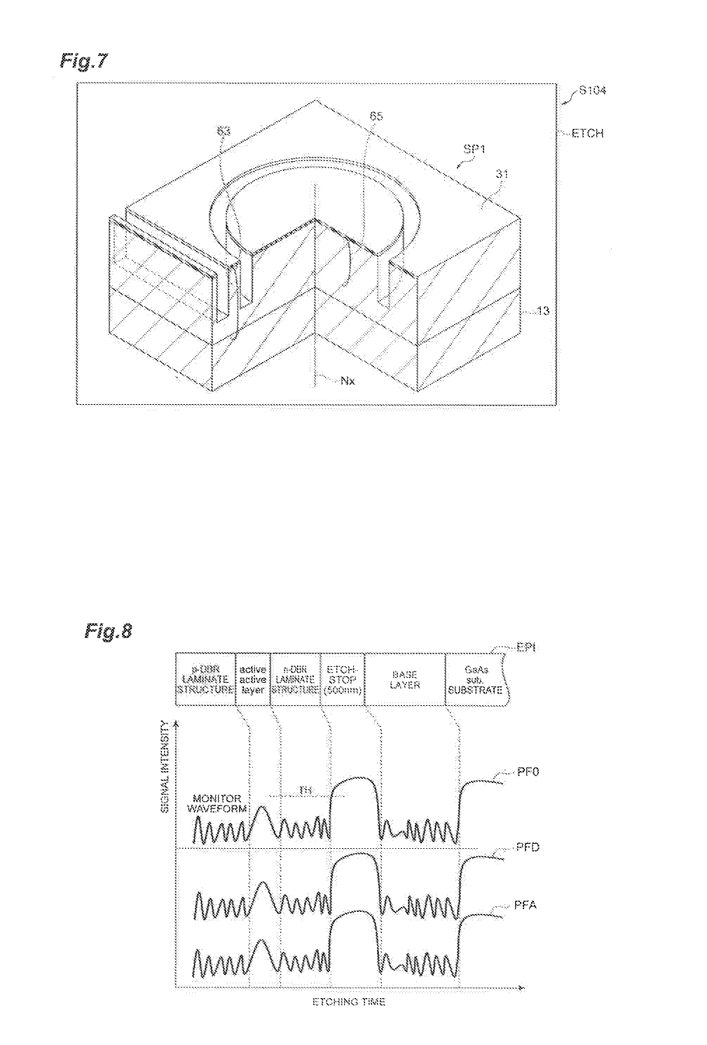

FIG. 8 shows an output waveform generated from the wavelength-monitoring end point detector in etching the epitaxial substrate with the mask 31. In the waveform of FIG. 8, the semiconductor laminate and the substrate are etched in the depth direction without the end point detection to obtain the entire waveform signal in etching the semiconductor laminate of the epitaxial substrate. The epitaxial substrate has an epitaxial structure EPI shown in FIG. 8. The monitor waveform PF0 has sharp rising and falling edges at the upper and lower surfaces of the etch stop layer, respectively. The rising and falling edges are made abrupt to indicate the start and end of etching of the etch stop layer. The amount of constituent elements (or ions thereof) in the plasma is a superposition of the contributions from the etching of the device area 32 and the etching of the accessary area 33. The mask 31 has a pattern allowing the aperture ratio of the device area 32 to be not so different from the aperture ratio of the accessary area 33, so that in the plasma, the contribution (a monitoring waveform PFD) from constituent elements (or ions thereof) produced in etching the device area 32 is not much different from the contribution (monitoring waveform PFA) from constituent elements (or ions thereof) produced in etching the accessary area 43. This result is obtained by adjusting the aperture ratio of the mask with respect to an area of the single device section rather than an area of the shot.

FIG. 9 shows an output waveform which the wavelength monitoring end point detector generates in etching the epitaxial substrate with the mask 41. In the waveform of FIG. 9, the semiconductor laminate and the substrate are etched in the depth direction without the end point detection to obtain the entire waveform signal in etching the semiconductor laminate of the epitaxial substrate. This epitaxial substrate has the same structure as the epitaxial structure EPI shown in FIG. 8. The amount of constituent elements (or ions thereof) in the plasma is a superposition of the contributions from the etching of the device area 42 and the etching of the accessary area 43. The mask 41 has a pattern allowing the aperture ratio of the device area 42 to be lamely different from the aperture ratio of the accessary area 43, so that in the plasma, the contribution (contribution to the plasma) from constituent elements (and/or ions thereof) produced by etching of the device area 32 is different from the contribution from constituent elements (or ions thereof) produced by etching of the accessary area 43. As shown by a dashed line BOX in FIG. 9, the rising and falling edges indicating the start and end of etching of the etch-stop layer are made largely rounded. This dullness results from the superposition of the signals from the etching of the device area 42 and the etching of the accessary area 43.

After installing the end point detector 42a, as shown in FIG. 7, a gas containing boron trichloride and chlorine is supplied to the etching apparatus ETCH to etch the epitaxial substrate EP by using the plasma etching method. In the plasma etching process, the device area and the accessary area are etched according to the pattern defined by the mask 31. The monitoring area also includes the laminate 11. In the former half of the etching, the second stacked semiconductor layer 19 and the semiconductor region 17 are processed, and in the latter half of the etching, the first stacked semiconductor layer 15 is processed. In the present embodiment, the first stacked semiconductor layer 15 includes a GaAs/AlGaAs multilayer film, and the substrate 13 is made of GaAs. In the present fabricating method and monitoring method, the end point detector 42a monitors light emission indicating that constituent elements peculiar to the compound semiconductor to be etched appear in the plasma. A specific constituent element (for example, gallium) may be contained in, for example, an etch stop layer in the epitaxial substrate. Plasma emission from the constituent element (or ion) of this kind is received via the view port 51a by the detector. The end point detection is performed by monitoring changes in intensity of desired light.

The description of the major steps in the fabricating method follows the description of the above example. After the setup of the end point detector 52a (end point detection monitor), etching is ready to start. In the fabrication of the vertical cavity surface emitting laser, the laminate structure is etched, in response to the end point detection by the end point detector 52a, the plasma etching is stopped. As shown in FIG. 7, the etching produces the substrate product SP1 from the epitaxial substrate EP. The substrate product SP1 includes the mask 31, the substrate 13, the semiconductor structure 63, and a semiconductor post 65.

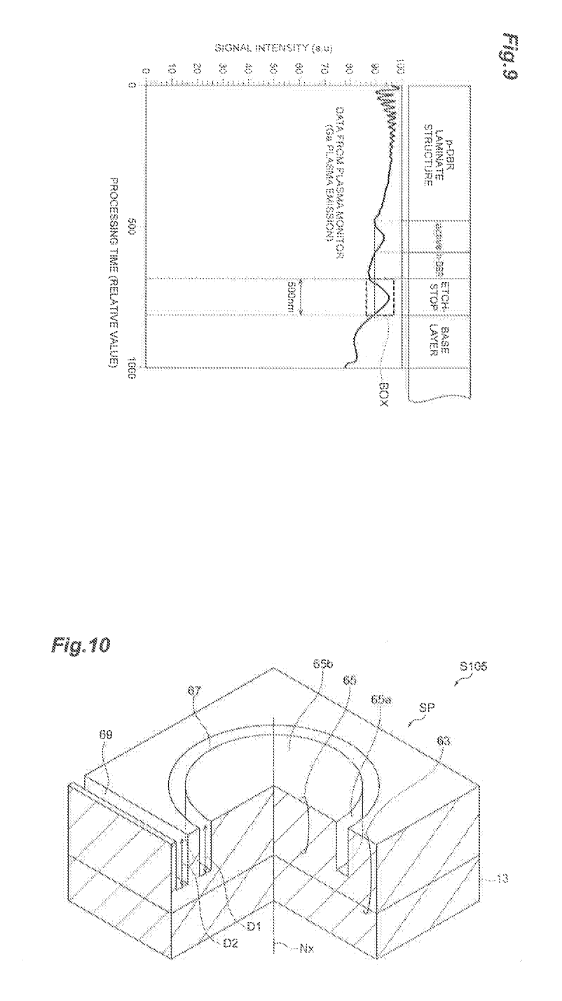

After taking the substrate product SP1 out from the etching apparatus ETCH, in step S105, as shown in FIG. 10, the mask 31 is removed therefrom to obtain the substrate product SP produced from the epitaxial substrate EP by etching. The substrate product SP includes the substrate 13, the semiconductor structure 63, and the semiconductor post 65. The semiconductor post 65 includes a first distributed Bragg reflector, an active layer, and a second its distributed Bragg reflector, which comes from the epitaxial structure in the epitaxial substrate EP. The first distributed Bragg reflector, the active layer, and the second distributed Bragg reflector are arranged in the direction of the normal axis Nx. The semiconductor post 65 includes a side face 65a extending in the direction of the normal axis Nx and an upper face 65b extending along a plane intersecting with the direction of the normal axis Nx.

The substrate product SP includes a first groove 67 defining a semiconductor post 65, and a second groove 69 disposed in the semiconductor structure 63 and running across the device section. The first groove 67 has a first depth D1, and the second groove 69 has a second depth D2. The ratio (D2/D1) of the second depth D2 to the first depth D1 is 1% or more, and the ratio (D2/D1) is 3% or less. Such a ratio in the range can be accomplished by adjusting the width of the first opening 34a of the mask 31 (the width of the first groove 67) and the width of the second opening 34b of the mask 31 (the width of the second groove 69). Similarly, the depth of the groove that corresponds to the openings 34k, 34m, 34n, 34p, 34q, 34r, 34s in the accessary area 33 falls within s dispersion range of 1% or more and 3% or less as above. Such a ratio in the above range can be accomplished by adjusting the widths of the openings 34k, 34m, 34n, 34p, 34q, 34r, 34s and the first opening 34a of the mask 31 (the width of the first groove 67).

In the method for fabricating the surface emitting laser, the semiconductor multilayer film including the first stacked semiconductor layer 15 and the second stacked semiconductor layer 19 constituting the distributed Bragg reflectors, and the semiconductor region 17 in the laminate 11 is etched. Processing the semiconductor multilayer film may form an array of semiconductor posts 65 of desired height. Using the end point detector allows detection of the completion of the etching. Inventor's teachings reveal that the signal from the end point detector represents the etching progress in an area wider than that of the single device section, and the product in the fabricating process contains the device area 32 including the device sections SECT and the accessary area 33 including a structure used in subsequent processes. During the etching, the end point detector generates an output signal which includes superposition of the signals related to these areas. It is found that the superposition degrades the accuracy of the end point detection. The superposition occurs, however, in the fabricating process for the surface emitting laser including the device area containing an array of device sections SECT and the accessary area 33. In the etching process, it is important to accurately monitor the progress of etching in the area containing the array of device sections SECT. In the embodiment, it is found that the deterioration in accuracy of the end point detection caused by the superposition results from the difference between the progresses of etching in the accessary area 33 and the device sections SECT. Specifically, the difference between the progresses of etching in these areas is mainly associated with the difference between the aperture ratio in the accessary area and the aperture ratio in the device area including the device sections. The pattern of the mask 31 for etching is adjusted such that the aperture ratio of the device area 32 and the aperture ratio of the accessary area 33 in the single device area are close to each other. The adjustment can reduce deterioration, caused by superposition, in accuracy of the end point detection.

In step S106, as shown in FIG. 11, the passivation film 71 is grown on the entire surface. The passivation film 71 may be formed by, for example, plasma CVD, and includes a silicon-based inorganic insulating film made of SiN, SiON or SiO₂, for example. The passivation film 71 has a film thickness adjusted so as to act as a high reflection film with respect to the wavelength of the light emitted from the surface emitting laser.

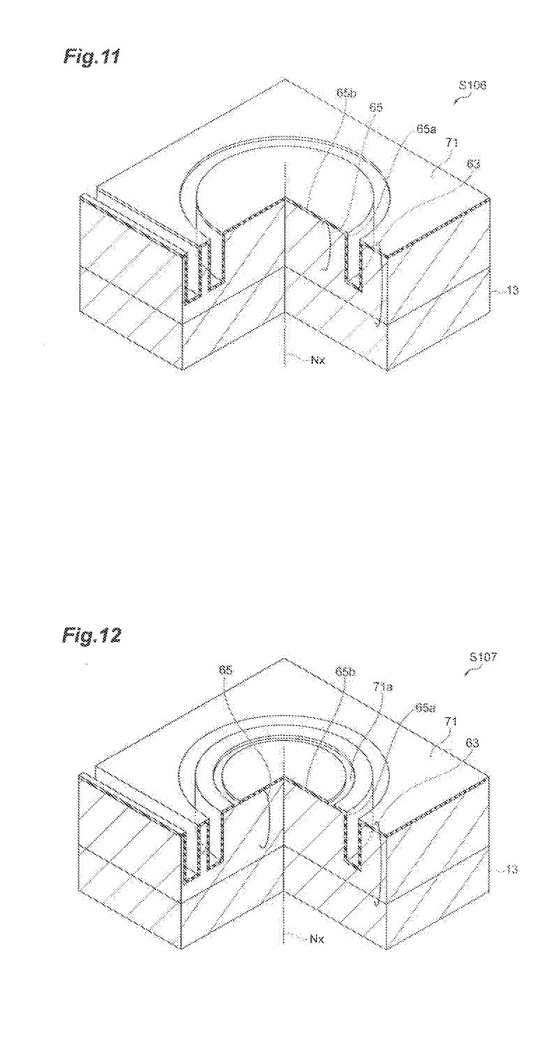

In step S107, after forming the passivation film 71, as shown in FIG. 12, an opening is formed in the passivation film 71 by etching and photolithography. In the present embodiment, the passivation film 71 has an opening 71a located on the upper face 65b of the semiconductor post 65.

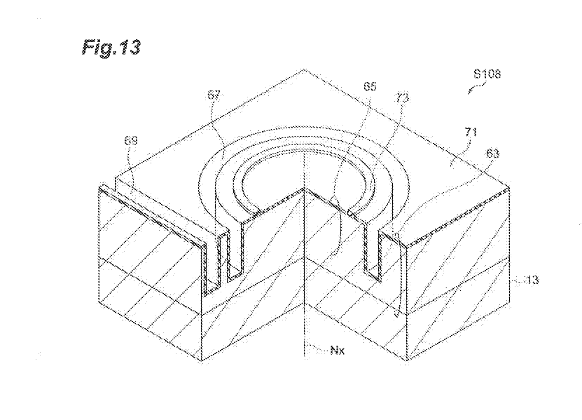

In step S108, after forming the opening 71a in the passivation film 71, the electrode 73 is formed in the opening 71a as shown in FIG. 13. The electrode 73 may include a Tl/Pt/Au laminate structure. The electrode 73 is in contact with the upper face 65b of the semiconductor post 65 through the opening 71a.

These steps complete the surface emitting laser. FIG. 13 shows the appearance of the surface emitting laser thus fabricated of a semiconductor chip.

As described above, the method of fabricating the surface emitting laser according to the present embodiment provides a surface emitting laser with a semiconductor post having a desired height. The surface emitting laser includes the semiconductor structure 63, the semiconductor post 65, the first groove 67

What is claimed is:

1. A method for fabricating a surface emitting laser comprising the steps of:
growing a semiconductor laminate on a substrate to form an epitaxial substrate;
forming a mask on the epitaxial substrate, the mask defining a semiconductor post of the surface emitting laser, the mask having a device area and an accessary area;
after forming the mask, placing the epitaxial substrate in a chamber of an etching apparatus with an end point detector;
carrying out etching of the semiconductor laminate with the mask in the chamber of the etching apparatus; and
stopping the etching of the semiconductor laminate in response to a detection signal from the end point detector in the etching apparatus,
wherein the device area includes a plurality of device sections arranged in row and column,
each of the device sections has an opening,
the device area has an aperture ratio (OPD/SC) having a first value,
the aperture ratio (OPD/SC) of the device area being defined as a total area (OPD) of the opening in each device section to an area (SC) of the device section,
the accessary area has an opening pattern,
the accessary area has an aperture ratio having a second value configured to have substantially the same value as the first value, the aperture ratio of the accessary area being defined as an area of the opening pattern in a portion having an area, which is equal to the area of the device section, in the accessary area.

2. The method according to claim 1, wherein each of the device sections in the device area includes a first opening having a closed shape defining a pattern for the semiconductor post,
the accessary area has an area larger than that of the device section, and
the second value is equal to or larger than a lower limit which is smaller by 0.02 with respect to the first value and is equal to or less than an upper limit which is larger by 0.02 with respect to the first value.

3. The method according to claim 2, wherein the device area includes a second opening different from the first opening disposed in each of the device sections.

4. The method according to claim 1, wherein the end point detector includes a spectrometer for monitoring an optical emission in the etching.

5. The method according to claim 1, wherein the etching is carried out by using an inductive-coupling plasma reactive-ion etching method.

6. The method according to claim 1, wherein the etching is carried out by using BCl₃ as an etchant.

7. The method according to claim 1, wherein the opening pattern in the accessary area includes a plurality of openings that defines an alignment mark.
